(19) United States
(12) Patent Application Publication
(10) Pub. No.: US 2026/0354183 A1
(43) Pub. Date: Nov. 5, 2026

(54) SEMICONDUCTOR PACKAGE ASSEMBLY WITH A DIRECT WATER COOLING SYSTEM

(71) Applicant: STATS ChipPAC Management Pte. Ltd., Singapore (SG)

(72) Inventors: JiSeon LEE, Incheon (KR); HeeSoo LEE, Incheon (KR); EunHee MYUNG, Gyeonggi-do (KR)

(21) Appl. No.: 19/661,705

(22) Filed: Apr. 29, 2026

(30) Foreign Application Priority Data
Apr. 30, 2025 (CN) 202510568284.2

(51) Int. Cl. H10W 40/30; H10W 40/20; H10W 40/40; H10W 90/00; H10W 90/20; H10W 74/15

(52) U.S. Cl. CPC H10W 40/30; H10W 40/242; H10W 40/40; H10W 90/20; H10W 90/722; H10W 90/736; H10W 74/15

(57) ABSTRACT

A semiconductor package assembly comprises: a package substrate, a bottom semiconductor die mounted on the package substrate with a set of through vias coupled to the package substrate, and exposed on its front surface; a set of interconnection posts mounted on the bottom semiconductor die and aligned with and connected with one of the set of through vias; a top semiconductor die mounted on the set of interconnection posts and electrically coupled to the package substrate through the set of interconnection posts and the set of through vias; and a lid mounted on the package substrate and defines a chamber for accommodating the bottom semiconductor die and the top semiconductor die, and wherein the lid comprises an inlet and an outlet passing therethrough and in fluid communication with the chamber to allow a coolant to flow into and out of the chamber.

### TECHNICAL FIELD

The present application generally relates to semiconductor technologies, and more particularly, to a semiconductor package assembly with a direct water cooling system, and a method for making such semiconductor package assembly.

### BACKGROUND OF THE INVENTION

The semiconductor industry is constantly faced with complex integration challenges as consumers want their electronics to be smaller, faster and higher performance with more and more functionalities packed into a single device. In some semiconductor packages, a Package-in-Package (PiP) or Package-on-Package (PoP) process is applied, which combines two or more integrated circuit (IC) packages together. The PiP or PoP devices can more efficiently use space, and reduce lengths of signal paths between the packages. In a typical PiP or PoP device, one or more pre-molded semiconductor packages may be mounted onto another semiconductor package through an interposer or other similar structures.

However, it is noted that certain electronic components such as logic circuit chips in the PiP or PoP devices may generate significant heat during operation, which may not be well dissipated to the external environment due to the compact package structure of the PiP or PoP devices. Therefore, a need exists for further improvement to semiconductor package assemblies with a compact structure.

### SUMMARY OF THE INVENTION

An objective of the present application is to provide a semiconductor package assembly with improved heat dissipation performance.

According to an aspect of the present application, a semiconductor package assembly is disclosed. The semiconductor package assembly comprises: a package substrate, a bottom semiconductor die mounted on the package substrate, wherein the bottom semiconductor die comprises a set of through vias passing therethrough and electrically coupled to the package substrate, and wherein the set of through vias are exposed from a front surface of the bottom semiconductor die; a set of interconnection posts mounted on the bottom semiconductor die and each being vertically aligned with and connected with one of the set of through vias; a top semiconductor die mounted on the set of interconnection posts and electrically coupled to the package substrate through the set of interconnection posts and the set of through vias; and a lid mounted on the package substrate, wherein the lid defines with the package substrate a chamber for accommodating the bottom semiconductor die and the top semiconductor die, and wherein the lid comprises an inlet and an outlet passing therethrough and in fluid communication with the chamber to allow a coolant to flow into and out of the chamber, such that heat generated by the top semiconductor die and the bottom semiconductor die can be transferred out of the chamber.

According to another aspect of the present application, a semiconductor package assembly is disclosed. The semiconductor package assembly comprises: a package substrate; a bottom semiconductor die mounted on the package substrate, wherein the bottom semiconductor die comprises a set of through vias passing therethrough and electrically coupled to the package substrate, and wherein the set of through vias are exposed from a front surface of the bottom semiconductor die; a set of interconnection posts mounted on the bottom semiconductor die and each being vertically aligned with and connected with one of the set of through vias; a top semiconductor die mounted on the set of interconnection posts and electrically coupled to the package substrate through the set of interconnection posts and the set of through vias; and a lid mounted on the bottom semiconductor die, wherein the lid defines with the bottom semiconductor die a chamber for accommodating the set of interconnection posts and the top semiconductor die, and wherein the lid comprises an inlet and an outlet passing therethrough and in fluid communication with the chamber to allow a coolant to flow into and out of the chamber, such that heat generated by the top semiconductor die and the bottom semiconductor die can be transferred out of the chamber.

According to a further aspect of the present application, a method for making a semiconductor package assembly is provided. The method comprises: providing a package substrate; providing a top semiconductor die with a set of upper interconnection posts extending downward from a back side of the top semiconductor die; mounting a bottom semiconductor die comprising a set of through vias passing therethrough onto the package substrate such that the set of through vias are electrically coupled to the package substrate and exposed from a front surface of the bottom semiconductor die; mounting the top semiconductor die on the bottom semiconductor die via a set of lower interconnection posts such that each of the set of upper interconnection posts is vertically aligned with and connected with one of the set of through vias through one of the set of lower interconnection posts; and mounting a lid comprising an inlet and an outlet passing therethrough on the package substrate to define with the package substrate a chamber for accommodating the bottom semiconductor die and the top semiconductor die and allow a coolant to flow into the chamber through the inlet and out of the chamber through the outlet.

According to another aspect of the present application, a method for making a semiconductor package assembly is provided. The method comprises: providing a package substrate; providing a top semiconductor die with a set of upper interconnection posts extending downward from a back side of the top semiconductor die; mounting a bottom semiconductor die comprising a set of through vias passing therethrough onto the package substrate such that the set of through vias are electrically coupled to the package substrate and exposed from a front surface of the bottom semiconductor die; mounting the top semiconductor die on the bottom semiconductor die via a set of lower interconnection posts such that each of the set of upper interconnection posts is vertically aligned with and connected with one of the set of through vias through one of the set of lower interconnection posts; and mounting a lid comprising an inlet and an outlet passing therethrough on the bottom semiconductor die to define with the bottom semiconductor die a chamber for accommodating a set of interconnection posts mounted on the bottom semiconductor die and the top semiconductor die and allow a coolant to flow into the chamber through the inlet and out of the chamber through the outlet.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a semiconductor package assembly according to an embodiment of the present application.

FIG. 2 illustrates a semiconductor package assembly according to an embodiment of the present application.

FIG. 3 illustrates a semiconductor package assembly according to an embodiment of the present application.

FIGS. 4A-4M illustrate a method for making a semiconductor package assembly according to an embodiment of the present application.

FIGS. 5A-5B illustrate a method for making a semiconductor package assembly according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, conventional semiconductor package assemblies may not have satisfactory heat dissipation performance due to their compact structure as well as significant heat generated by electronic components encapsulated within the semiconductor package assemblies. To address the heat dissipation issue, the inventors of the present application have conceived incorporating into a semiconductor package assembly a direct cooling system to provide cooling for the internal electronic components. The direct cooling system may include a chamber which accommodates the internal electronic components and a coolant to flow into and out of the chamber. In this way, the heat dissipation performance of the semiconductor package assembly can be improved significantly.

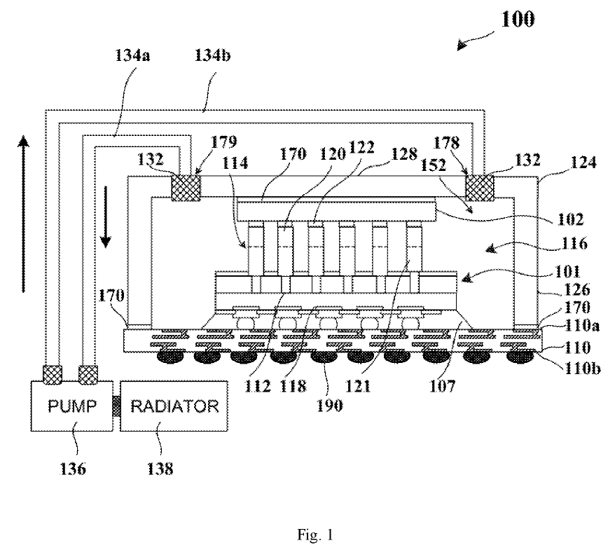

FIG. 1 illustrates a semiconductor package assembly 100 according to an embodiment of the present application. As shown in FIG. 1, the semiconductor package assembly 100 incorporates a bottom semiconductor die 101 and a top semiconductor die 102 that are bonded together, and a lid 124 mounted generally topmost of the semiconductor package assembly 100.

As shown in FIG. 1, the semiconductor package assembly 100 includes a package substrate 110 which has a front surface 110a (facing upward in the direction shown in FIG. 1) and a back surface 110b that is opposite to the front surface 110a. By way of example, the package substrate 110 may include a printed circuit board (PCB), a carrier substrate, a semiconductor substrate with electrical interconnections, a ceramic substrate, a laminate interposer, a strip interposer, a leadframe, or other suitable substrates. The package substrate 110 may include any structure on or in which an integrated circuit system can be fabricated. In some examples, the package substrate 110 may include redistribution structures having one or more dielectric layers and one or more conductive layers between and through dielectric layers. The conductive layers may define pads, traces and plugs through which electrical signals or voltages can be distributed horizontally and vertically across the redistribution structures.

Still referring to FIG. 1, the bottom semiconductor die 101 is mounted on the package substrate 110 via a back-end-of-line (BEOL) layer 118 which may be formed or integrated with the bottom semiconductor die 101 during fabrication of the bottom semiconductor die 101 and some other interconnection structures such as solder bumps. An underfill material 107 may be filled between the bottom semiconductor die 101 and the package substrate 110 and around the solder bumps, to enhance the attachment of the bottom semiconductor die 101 to the package substrate 110. It can be appreciated that the BEOL layer 118 may be adjacent to or close to an active region of the bottom semiconductor die 101 where transistors may be formed. In other words, the active region of the bottom semiconductor die 101 can be generally facing towards the package substrate 110 and be electrically coupled to the package substrate 110 via the BEOL layer 118 and the solder bumps connected thereto. On the other hand, the other side of the bottom semiconductor die 101 which is away from the BEOL layer 118, i.e., the front side of the bottom semiconductor die 101 where transistors or other components or conductive patterns may not be formed, is facing away from the package substrate 110 and exposed to some upper components or structures of the semiconductor package assembly 100. It can be appreciated the bottom semiconductor die 101 may have other specific structures as desired.

A set of through vias 112 may pass through the bottom semiconductor die 101, each of which may have a bottom end electrically coupled the BEOL layer 118 and a top end exposed from a front surface of the bottom semiconductor die 101. The through vias 112 may be formed at regions of the bottom semiconductor die 101 where no transistors or active regions are formed, to avoid undesired connection to the active regions and damages or disfunctions to the circuitry of the bottom semiconductor die 101. In some other embodiments, the set of through vias 112 may include conductive pillars, copper balls, micro bumps, etc. In some complex package structures, it can be understood that multiple layers of through vias can be formed to achieve more complex interconnect structures. For example, when multiple bottom semiconductor dice are stacked together, the set of through vias 112 may pass through the multiple die layers to realize vertical interconnections across the multiple bottom semiconductor dice.

The top ends of the through vias 112 which are exposed from the bottom semiconductor die 101 provide for possibility of connecting further elements on the bottom semiconductor die 101. As such, a set of interconnection posts 114 are mounted on the bottom semiconductor die 101, and each interconnection post 114 is vertically aligned with and electrically connected with one of the set of through vias 112. In particular, each of the set of interconnection posts 114 may include an upper portion 120 and a lower portion 121 which are bonded together using a suitable joining process such as thermocompression bonding or solder reflowing. The interconnection posts 114 not only provide for electrical connection to the through vias 112 but also elevate components which are to be mounted to the bottom semiconductor die 101. In some embodiments, all of the through vias 112 and the interconnection posts 114 are formed of copper, or any other appropriate metal or conductive materials to match the difference in thermal expansion coefficient between these materials as much as possible. In this way, the impact of thermal stress on the set of interconnection posts 114 to the bottom semiconductor die 101 and other structures can be reduced.

Still referring to FIG. 1, the semiconductor package assembly 100 further includes a top semiconductor die 102 which may be mounted on and electrically connected to the bottom semiconductor die 101 via the set of interconnection posts 114. In particular, a set of conductive pads 122 is formed on a back surface of the top semiconductor die 102, and each of the set of conductive pads 122 is vertically aligned with and connected with one of the set of interconnection posts 114. The set of conductive pads 122 may be formed of copper and connected with the set of interconnection posts 114 through conductive bumps, solder joint or other connection types. As such, the top semiconductor die 102 can be electrically coupled to the bottom semiconductor die 101, or particularly, the through vias 112 of the bottom semiconductor die 101, and then be further connected to the package substrate 110 via the electrical paths consisting substantially of the interconnection posts 114, the through vias 112, the BEOL layer 118 and solder bumps stacked on the package substrate 110. It can be seen that, besides electrically connecting the top and bottom semiconductor dice 101 and 102 with each other, the set of interconnection posts 114 also provide mechanical support for the top semiconductor die 102, to allow a space between the top and bottom dice 101 and 102. A coolant such as water may be filled in the space and circulate therein to dissipate heat generated from the semiconductor dice 101 and 102, which will be elaborated below. It can be appreciated that the coolant may not be electrically conductive, and thus, it may not electrically connect different interconnection posts 114. For example, the coolant may be deionized water.

The top and bottom semiconductor dice 101 and 102 may be any of a variety of types of semiconductor dice. For example, the top and the bottom semiconductor dice may include a logic chip such as a central processing unit (CPU) or a graphics processing unit (GPU), a memory device such as a high bandwidth memory (HBM), a digital signal processor (DSP), a radiofrequency (RF) circuit, a wireless baseband system-on-chip (SoC) processor, a sensor, an application specific integrated circuit, etc.

Still referring to FIG. 1, a lid 124 is stacked on and cover the top semiconductor die 102, as well as other components of the semiconductor package assembly 100. The lid 124 has a support portion 126 which is attached to the package substrate 110, and a top plate 128 connected to and supported on the support portion 126. For example, the support portion 126 may take the form of a side wall which can have circular or rectangular layout. In some embodiments, the lid 124 can be attached onto the top semiconductor die 102, e.g., via an adhesive material or a thermally conductive material, which may provide an additional heat dissipation path for the top semiconductor die 102. In some embodiments, the lid 124 may have other support structure to improve stability. An adhesive material 170 may be formed between the support portion 126 and the package substrate 110, and optionally between the top plate 128 and the top semiconductor die 102. The adhesive material 170 can be various types of adhesives such as epoxy resin and conductive adhesives, which allows for reliable support and may also dissipate heat generated by the package substrate 110 and the top semiconductor die 102 to the external environment.

As can be seen from FIG. 1, the lid 124 defines with the package substrate 110 a chamber 116 for accommodating the bottom semiconductor die 101, the top semiconductor die 102 and the set of interconnection posts 114. Also, a coolant such as water can be filled within the chamber 116 to be in direct contact with the semiconductor dice 101 and 102 within the chamber 116. The chamber 116 can be generally sealed to avoid undesired coolant leakage. In the embodiment, an inlet 178 and an outlet 179 may be formed to pass through the lid 124 and be in fluid communication with the chamber 116 to allow the coolant to flow into and out of the chamber 116. The inlet 178 can receive the coolant from an external coolant container, and the outlet 179 can output the coolant to the external coolant container, such that heat generated by the top semiconductor die 102 and the bottom semiconductor die 101 can be transferred out of the chamber 116. Moreover, the inlet 178 and the outlet 179 may be located on opposite sides of the top semiconductor die 102, with the top plate 128 of the lid 124 formed between the inlet 178 and the outlet 179 and attached to the top semiconductor die 102. At the same time, heat generated by the top semiconductor die 102 can be transferred to the outside by the lid 124 via the adhesive layer 170. In some embodiments, the top plate 128 of the lid 124 may be designed with a relatively small thickness to allow better heat dissipation through the lid 124. It can be appreciated that the lid 124 may include liquid crystal polymer, steel or any other suitable materials.

A pipe 134a is used to couple the outlet 179 of the lid 124 to a pump 136, and another pipe 134b is used to couple the inlet 178 of the lid 124 to the pump 136. According to the configuration of the pump 136, the pipe 134b can bring the coolant into the chamber 116 and the pipe 134a can bring the coolant out of the chamber 116, thereby circulating the coolant within the pipes 134a and 134b and the chamber 116. The pipes 134a and 134b may include polyvinyl chloride (PVC), polyurethane (PU), polyethylene terephthalate glycol (PETG), metal such as copper or aluminum, etc. Further, two valves 132 may be disposed at the inlet 178 and the outlet 179 of the lid 124 to regulate a flow rate of the coolant within the chamber 116. For example, when the semiconductor package assembly 100 is operating with a high power, i.e., more heat may be generated during the operation, the valves 132 may be regulated to accelerate the flow rate of the coolant. As shown in FIG. 1, a radiator 138 is coupled to the pump 136 to cool the coolant when it comes into the pump 136. The radiator 138 may be a passive radiator or an active radiator, which can cool the coolant down to a lower temperature. Therefore, the coolant in the pipe 134a and 134b may be circulated (represented by arrows in FIG. 1) and cooled down efficiently through the pump 136 and the radiator 138.

The components and structures described above are generally mounted on the front surface 110a of the package substrate 110, while a plurality of conductive bumps 190 can be formed on the back surface 110b of the package substrate 110. In the example shown in FIG. 1, the conductive bumps 190 are illustrated as solder bumps, but the present application is not limited thereto. In some other embodiments, the conductive bumps 190 may include conductive pillars, copper balls, etc. In a case where the semiconductor package assembly 100 is mounted on an external device or substrate such as a printed circuit board (PCB), the conductive bumps 190 may be used for electrically connecting the semiconductor package assembly 100 to the external device or substrate.

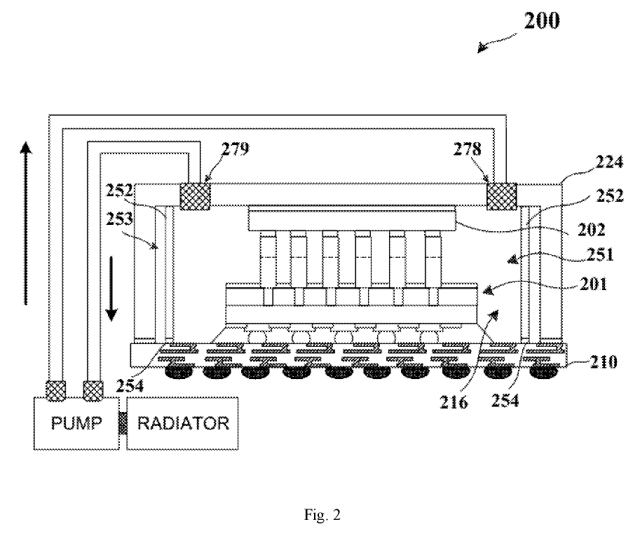

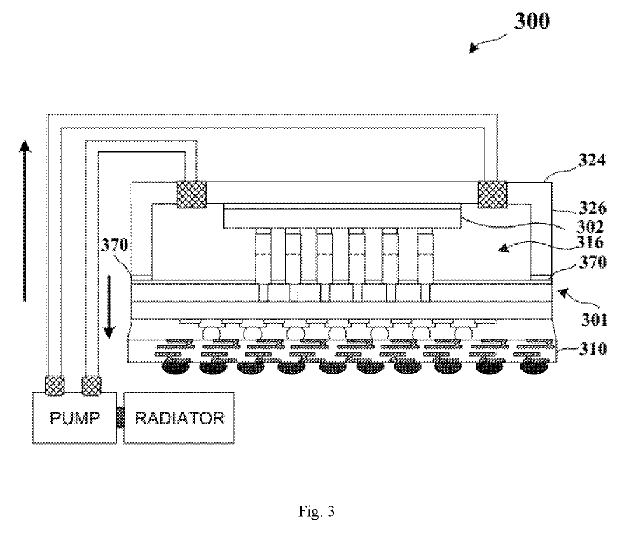

Various modifications can be made to the semiconductor package assembly 100 shown in FIG. 1. FIGS. 2 and 3 illustrate two semiconductor package assemblies 200 and 300 according to other embodiments of the present application, respectively, with certain changes to the semiconductor package assembly 100 shown in FIG. 1.

In the example shown in FIG. 2, a dam structure 252 made of a dielectric material or a metal is formed inside a chamber 216 and separates the chamber 216 into an inner portion 251 and an outer portion 253. The inner portion 251 surrounds a bottom semiconductor die 201 and a top semiconductor die 202 and is in fluid communication with an inlet 278 and an outlet 279 of a lid 224 through which a coolant can be pumped into or out of the inner portion 251. That is, the inner portion 251 can be filled with the coolant. In contrast, the outer portion 253 is separated from the inner portion 251 by the dam structure 252, and thus, may be or may not be filled with the coolant. In this embodiment, the dam structure 252 is designed to surround the top semiconductor die 202 and the bottom semiconductor die 201, and is connect to the lid 224 at its top side and a package substrate 210 on its bottom side. For example, the dam structure 252 can take the form of a cylindrical sleeve, or any other appropriate structures. In some embodiments, the dam structure 252 can also have alternative configurations to help manage the thermal distribution within the chamber 216 by isolating different areas to optimize the thermal conduction path. It can be understood that in some embodiments a sealing structure such as a sealing ring 254 can be disposed between the dam structure 252 and the package substrate 210, or between the dam structure 252 and the lid 224 to improve the sealing performance of dam structure 252. For example, the sealing ring 254 may be made of an insulating polymer composite material such as epoxy resin.

As shown in FIG. 3 which shows another exemplary semiconductor package assembly 300, a bottom semiconductor die 301 with a relatively large layout or footprint is provided. For example, the bottom semiconductor die 301 may cover more than 80% of a front surface of a package substrate 310 where it is mounted. In such embodiments, there is insufficient space on the bottom semiconductor die 301 to mount a lid 324. In particular, the lid 324 is directly attached on the bottom semiconductor die 301, instead of being attached on a package substrate 310. The lid 324 defines a chamber 316 with the bottom semiconductor die 301. Also, a top semiconductor die 302 is mounted on the bottom semiconductor die 301 via a set of interconnection posts and within the chamber 316. Similarly, a coolant can be pump into and out of the chamber 316 for heat dissipation purpose.

The embodiments in FIGS. 2 and 3 both achieve more efficient cooling with a reduced volume of coolant. More space can be allocated for other components or functionalities within the semiconductor package assembly with less coolant. The flow velocity of the coolant can also be maintained at a high level to more quickly remove heat generated from the semiconductor package assembly.

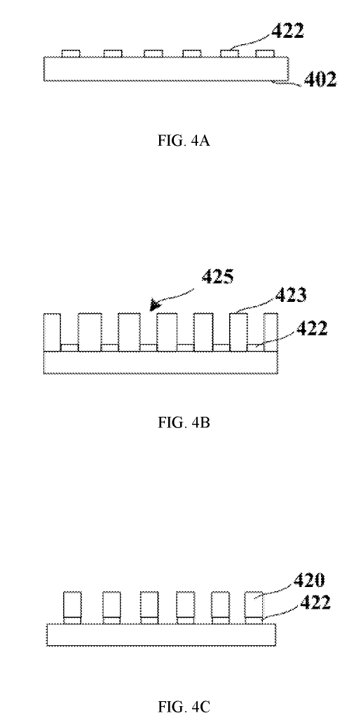

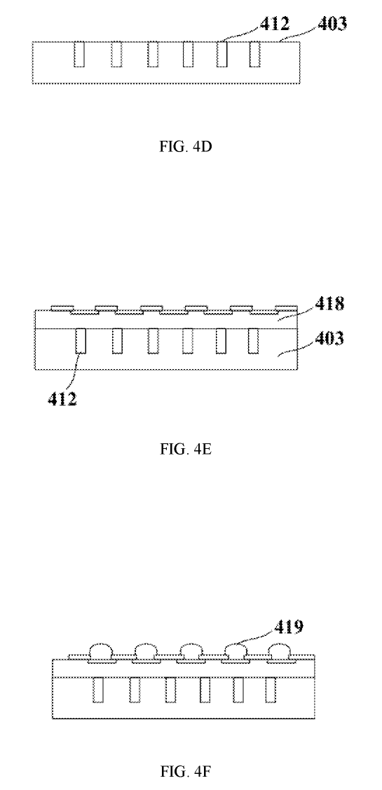

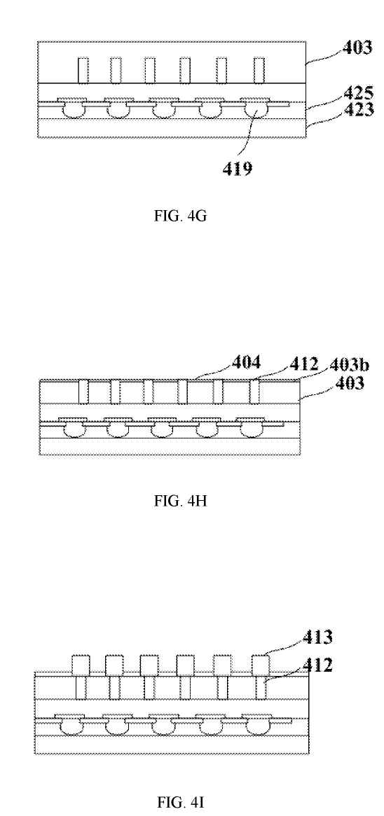

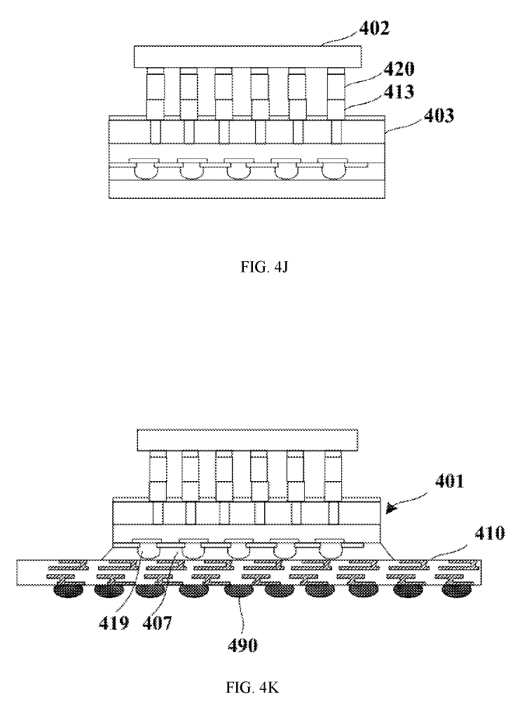

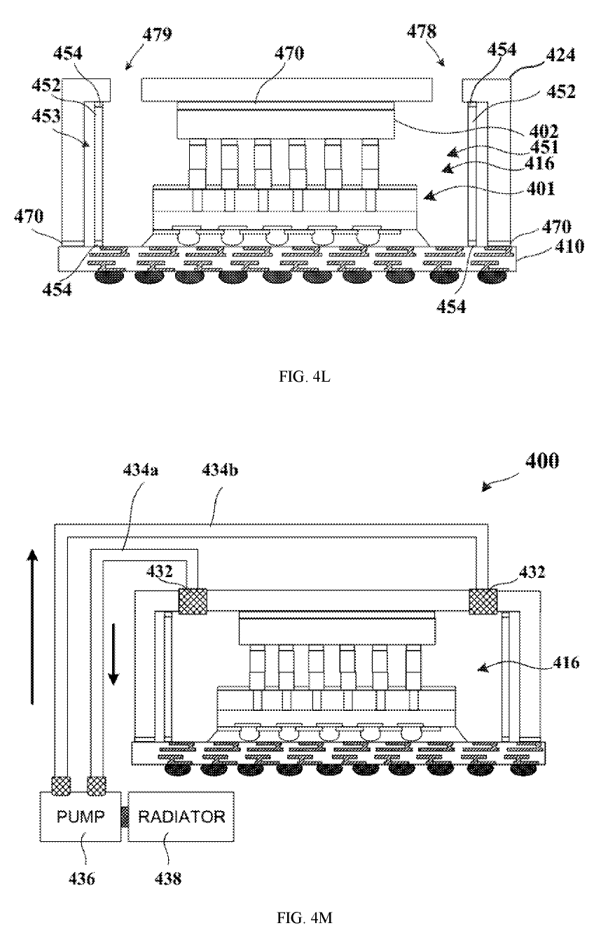

FIGS. 4A to 4H illustrate a method for making a semiconductor package assembly according to an embodiment of the present application. For example, the method can be used to make the semiconductor package assembly 200 shown in FIG. 2. It can be appreciated that the method may also be used to make the semiconductor package assembly 100 shown in FIG. 1 with some modifications. As the semiconductor package assembly is formed by assembling two semiconductor dice together, the two semiconductor dice can be prepared separately and later assembled with each other.

As shown in FIG. 4A, a top semiconductor die 402 can be prepared first. In particular, a set of conductive pads 422 are formed on a back surface of the top semiconductor die 402. The conductive pads 422 can be formed of copper or other similar metal or alloy materials. Next as shown in FIG. 4B, a photoresist material can be formed on the back surface of the top semiconductor die using a coating process and then forming a patterned photoresist layer 423 with a set of openings 425 using lithography. As a result, the set of openings 425 of the patterned photoresist layer 423 can each expose one of the set of conductive pads 422.

Next as shown in FIG. 4C, a conductive material such as copper can be filled in the set of openings to form a set of upper interconnection posts 420. Each of the upper interconnection posts 420 can be in direct contact with one of the conductive pads 422 and thus electrically connected with the conductive pad 422. As such, the top semiconductor die with the set of upper interconnection posts is prepared, after the patterned photoresist layer is removed by a dry etching process or a wet chemical stripping process.

FIGS. 4D-4M illustrate steps for preparing a bottom semiconductor die. As shown in FIG. 4D, a set of trenches may be formed at a front surface of a raw bottom semiconductor die 403 by etching. Then the set of trenches can be filled with a conductive material such as copper to form a set of through vias 412. The trenches may extend through the entire thickness of the raw bottom semiconductor die 403, and thus the through vias 412 may have a height smaller than the thickness of the raw bottom semiconductor die 403. It can be understood that any excess conductive material may be removed by polishing to make sure that the front surface of the raw bottom semiconductor die 403 is flat and smooth for later packaging process.

Next, as shown in FIG. 4E, a back-end-of-line (BEOL) layer 418 is formed on the front surface of the raw bottom semiconductor die 403 to cover the set of through vias 412 and be electrically connected with the set of through vias 412. Specifically, the BEOL layer 418 can be obtained by depositing a metal layer of copper or aluminum and creating a set of pad openings on a front surface of the metal layer where a set of solder bumps 419 will be formed later, as shown in FIG. 4F. In some alternative embodiments, the set of solder bumps 419 may be formed in any other appropriate bumping processes, for example, using a composite bumping process. With the composite bumping process, bumps each having a composite structure including a copper pad and a solder ball may be formed.

Next, as shown in FIG. 4G, the raw bottom semiconductor die 403 can be flipped over, and then attached onto a temporary carrier 423 which can provide support and stability during further processing steps. A flexible layer 425 such as a flexible tape can be used to attach the raw bottom semiconductor die 403 onto the temporary carrier 423, without causing damages to the solder bumps 419. The flexible layer 425 can be an adhesive material which can be easily removed during further processing steps without damaging the raw bottom semiconductor die 403.

Next, as shown in FIG. 4H, an excess portion of the raw bottom semiconductor die 403 may be removed by grinding, and accordingly, the through vias 412 can be exposed from a back surface 403b of the raw bottom semiconductor die 403. A passivation layer 404 made of materials such as silicon nitride or silicon dioxide can be applied to cover both the back surface 403b of the raw bottom semiconductor die 403 and the exposed part of the set of through vias 412. The passivation layer 404 can protect the raw bottom semiconductor die 403 from oxidation and other forms of degradation.

Next, as shown in FIG. 4I, a set of lower interconnection posts 413 is formed on the set of through vias 412, with each post of the set of lower interconnection posts being aligned with a corresponding one of the set of through vias 412. The process of forming the set of lower interconnection posts is similar to that of process of forming the set of upper interconnection posts on the top semiconductor die, which will not be elaborated herein. In this way, the bottom semiconductor die is prepared and ready for assembling with the top semiconductor die.

FIGS. 4J illustrates the process of assembling the top semiconductor die 402 with the raw bottom semiconductor die 403 by aligning and bonding the set of upper interconnection posts 420 and the set of lower interconnection posts 413, both of which are made of copper material. This process can be performed using Cu-Cu bonding, during which a high temperature and a compression force are applied to the upper and lower parts of the posts, to achieve a reliable and conductive electrical connection between the top semiconductor die 402 and the bottom semiconductor die 403 via the interconnection posts. It can be understood that during the process of Cu-Cu bonding, additional support structures may be employed to ensure alignment and reduce stress between the top semiconductor die 402 and the bottom semiconductor die 403.

Next, as shown in FIG. 4K, the temporary carrier and the flexible layer thereon can be removed from the bottom semiconductor die. The bottom semiconductor die can be mounted onto a package substrate 410 via the set of solder bumps 419. Furthermore, an underfill material 407 may be filled between the bottom semiconductor die 401 and the package substrate 410 and around the set of bumps 419 under the bottom semiconductor die, to enhance the attachment of the bottom semiconductor die 401 to the package substrate 410. In addition, another set of solder bumps 490 can be mounted on the back surface of the package substrate 410 to allow the components on the package substrate 410 to be electrically connected to an external device when needed.

Next referring to FIG. 4L, a dam structure 452 may be attached on the package substrate 410 surrounding the top semiconductor die 402 and the bottom semiconductor die 401. Then a lid 424 with an inlet 478 and an outlet 479 is attached on the package substrate 410 via an adhesive layer 470. The lid defines a chamber 416 between the lid 424 and the substrate package 410. It should be noted that the dam structure 452 is formed within the chamber 416 and has a height equal to that of the chamber 416. As such, the dam structure 452 can separate the chamber 416 into an inner portion 451 and an outer portion 453. The top and bottom semiconductor dice are both inside the inner portion 451. Additionally, the adhesive layer 470 can also be formed between the lid 424 and the top semiconductor die 402 to enhance the connection. As a result, the lid 424 is can be further supported on the package substrate 410 by the top semiconductor die 402 and the dam structure 452. In this embodiment, a pair of sealing rings 454 can be formed between the dam structure 452 and the lid 424 and between the dam structure 452 and the package substrate 410 to improve sealing of the chamber 416 enclosed by the dam structure 452. A coolant such as deionized water can be filled within inner portion 451 of the chamber 416. In some embodiments, the step of attaching the dam structure can be omitted such that the coolant can be filled directly within the chamber 416.

Next, as shown in FIG. 4M, a pump 436 is coupled to a semiconductor package assembly 400, which is in fluid communication with the chamber through cooling pipes 434a and 434b to circulate the coolant within the chamber 416. Further, a radiator 438 is coupled with the pump 436 to cool the coolant. Two valves 432 are mounted in the cooling pipes 434a and 434b to regulate the flow of the coolant within the first and second fluidic channels.

After the various steps shown in FIGS. 4A-4M, the semiconductor package assembly can be obtained.

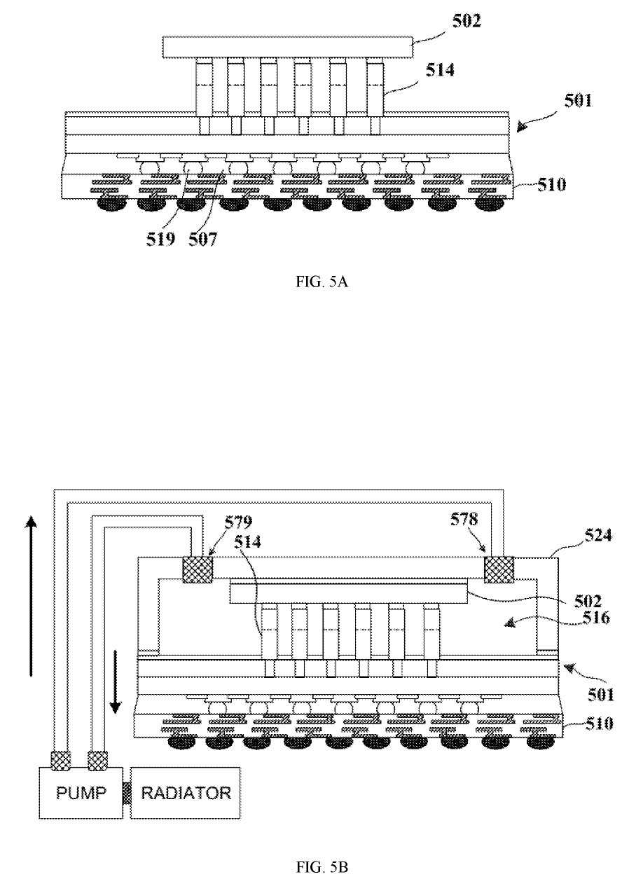

FIGS. 5A-5B illustrate another method for making a semiconductor package assembly. The method may be used to make the semiconductor package assembly 300 shown in FIG. 3.

As shown in FIG. 5A, a bottom semiconductor die 501 is attached to a package substrate 510 with an underfill material 507 filled between the bottom semiconductor die 501 and a package substrate 510 and around a set of bumps 519 under the bottom semiconductor die. A top semiconductor die 502 is electrically connected with the bottom semiconductor die 501 through a set of interconnection posts 514. The assembling of the top and bottom semiconductor dice and the package substrate is similar as the steps shown in FIGS. 4A-4K, which will not be elaborated herein. A difference from the embodiment shown in FIGS. 4A-4K is that the package substrate 510 has a relatively smaller layout or footprint than the package substate 410, compared with the bottom semiconductor die 501 or 401.

Next, as shown in FIG. 5B, a lid 524 having an inlet 578 and an outlet 579 is directly mounted on the bottom semiconductor die 501, instead of being mounted on the package substrate 510, to define with the bottom semiconductor die 501 a chamber 516 for accommodating a set of interconnection posts 514 mounted on the bottom semiconductor die 501 and the top semiconductor die 502 and allow a coolant to flow into the chamber 516 through the inlet 578 and out of the chamber 516 through the outlet 579.

After the steps shown in FIGS. 5A-5B, attaching cooling pipes and other cooling components which is the same as that shown in FIG. 4M and will not be repeated here.

The discussion herein includes numerous illustrative figures that show various portions of a semiconductor package assembly with a direct cooling system and a method for making such semiconductor package assembly. For illustrative clarity, such figures do not show all aspects of each example semiconductor package. Any of the example packages provided herein may share any or all characteristics with any or all other packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package assembly, comprising:
a package substrate;
a bottom semiconductor die mounted on the package substrate, wherein the bottom semiconductor die comprises a set of through vias passing therethrough and electrically coupled to the package substrate, and wherein the set of through vias are exposed from a front surface of the bottom semiconductor die;
a set of interconnection posts mounted on the bottom semiconductor die and each being vertically aligned with and connected with one of the set of through vias;
a top semiconductor die mounted on the set of interconnection posts and electrically coupled to the package substrate through the set of interconnection posts and the set of through vias; and
a lid mounted on the package substrate, wherein the lid defines with the package substrate a chamber for accommodating the bottom semiconductor die and the top semiconductor die, and wherein the lid comprises an inlet and an outlet passing therethrough and in fluid communication with the chamber to allow a coolant to flow into and out of the chamber, such that heat generated by the top semiconductor die and the bottom semiconductor die can be transferred out of the chamber.

2. The semiconductor package assembly of claim 1, wherein the lid is attached onto a front side of the top semiconductor die to allow heat exchange therebetween.

3. The semiconductor package assembly of claim 1, further comprising a dam structure formed inside the chamber and separating the chamber into an inner portion and an outer portion, wherein the inner portion surrounds the bottom semiconductor die and the top semiconductor die and is in fluid communication with the inlet and the outlet.

4. The semiconductor package assembly of claim 1, wherein the bottom semiconductor die is mounted on the package substrate via a back-end-of-line (BEOL) layer.

5. The semiconductor package assembly of claim 1, wherein the top semiconductor die comprises a set of conductive pads, and each of the set of conductive pads is vertically aligned with and connected with one of the set of interconnection posts.

6. The semiconductor package assembly of claim 5, wherein all of the through vias, the interconnection posts and the conductive pads are formed of copper.

7. The semiconductor package assembly of claim 1, wherein each of the set of interconnection posts comprises an upper portion and a lower portion which are bonded together.

8. The semiconductor package assembly of claim 1, wherein the top semiconductor die is coupled to the lid via an adhesive material.

9. The semiconductor package assembly of claim 1, wherein the lid is coupled to the package substrate via an adhesive material.

10. The semiconductor package assembly of claim 1, further comprising:
a pump in fluid communication with the inlet and outlet through respective cooling pipes to circulate the coolant within the cooling pipes and the chamber; and
a radiator in fluid communication with the pump to cool the coolant which is out of the chamber.

11. The semiconductor package assembly of claim 10, further comprises two valves mounted in the cooling pipes to regulate the flow of the coolant.

12. A semiconductor package assembly, comprising:
a package substrate,
a bottom semiconductor die mounted on the package substrate, wherein the bottom semiconductor die comprises a set of through vias passing therethrough and electrically coupled to the package substrate, and wherein the set of through vias are exposed from a front surface of the bottom semiconductor die;
a set of interconnection posts mounted on the bottom semiconductor die and each being vertically aligned with and connected with one of the set of through vias;
a top semiconductor die mounted on the set of interconnection posts and electrically coupled to the package substrate through the set of interconnection posts and the set of through vias; and
a lid mounted on the bottom semiconductor die, wherein the lid defines with the bottom semiconductor die a chamber for accommodating the set of interconnection posts and the top semiconductor die, and wherein the lid comprises an inlet and an outlet passing therethrough and in fluid communication with the chamber to allow a coolant to flow into and out of the chamber, such that heat generated by the top semiconductor die and the bottom semiconductor die can be transferred out of the chamber.

13. The semiconductor package assembly of claim 12, wherein the lid is attached onto a front side of the top semiconductor die to allow heat exchange therebetween.

14. The semiconductor package assembly of claim 12, wherein the top semiconductor die comprises a set of conductive pads, and each of the set of conductive pads is vertically aligned with and connected with one of the set of interconnection posts.

15. The semiconductor package assembly of claim 14, wherein all of the through vias, the interconnection posts and the conductive pads are formed of copper.

16. The semiconductor package assembly of claim 12, wherein each of the set of interconnection posts comprises an upper portion and a lower portion which are bonded together.

17. The semiconductor package assembly of claim 12, wherein the top semiconductor die is coupled to the lid via an adhesive material.

18. The semiconductor package assembly of claim 12, wherein the lid is mounted on the bottom semiconductor die via an adhesive material.

19. The semiconductor package assembly of claim 12, further comprising:
a pump in fluid communication with the inlet and outlet through respective cooling pipes to circulate the coolant within the cooling pipes and the chamber; and
a radiator in fluid communication with the pump to cool the coolant which is out of the chamber.

20. The semiconductor package assembly of claim 19, further comprises two valves mounted in the cooling pipes to regulate the flow of the coolant.
